(19) United States
(12) Patent Application Publication
(10) Pub. No.: US 2025/0031430 A1
(43) Pub. Date: Jan. 23, 2025

(54) EXTENDED BACKSIDE CONTACT IN STACK NANOSHEET

(71) Applicant: INTERNATIONAL BUSINESS MACHINES CORPORATION, ARMONK, NY (US)

(72) Inventors: Shahrukh Khan, Sandy Hook, CT (US); Biswanath Senapati, Mechanicville, NY (US); Utkarsh Bajpai, Delmar, NY (US); Ruilong Xie, Niskayuna, NY (US); Nicholas Anthony Lanzillo, Wynantskill, NY (US); Tenko Yamashita, Schenectady, NY (US); John Christopher Arnold, North Chatham, NY (US); Chen Zhang, Santa Clara, CA (US); Terence B. Hook, Jericho Center, VT (US); Junli Wang, Slingerlands, NY (US)

(21) Appl. No.: 18/356,291

(22) Filed: Jul. 21, 2023

(51) Int. Cl. H01L 29/417; H01L 21/8234; H01L 27/088; H01L 29/06; H01L 29/423; H01L 29/775

(52) U.S. Cl. CPC H01L 29/41766; H01L 21/823475; H01L 21/823481; H01L 27/088; H01L 29/0673; H01L 29/42392; H01L 29/775

(57) ABSTRACT

A microelectronic structure includes a first row of stack nano devices that includes a plurality of a first stacked nano FET devices and a second row of stack nano devices that includes a plurality of a second stacked nano FET devices. Each of the plurality of first nano stacked FET devices and each of the plurality of second stacked FET devices includes an upper stack transistor and a lower stack transistor. A gate cut located between the first row of stacked nano devices and the second row stacked nano devices. An interconnect located within gate cut. The interconnect is connected to a source/drain of one of the lower stacked transistors and the interconnect includes a non-uniform backside surface.

### BACKGROUND

The present invention generally relates to the field of microelectronics, and more particularly to formation of a backside contact for a stacked nanosheet device.

Nanosheet is the lead device architecture in continuing CMOS scaling. However, nanosheet technology has shown issues when scaling down such that as the devices become smaller and closer together, they are interfering with each other. Backside/buried power rails placement affects how the backside contacts are formed.

### BRIEF SUMMARY

Additional aspects and/or advantages will be set forth in part in the description which follows and, in part, will be apparent from the description, or may be learned by practice of the invention.

A microelectronic structure includes a first row of stack nano devices that includes a plurality of a first stacked nano FET devices and a second row of stack nano devices that includes a plurality of a second stacked nano FET devices. Each of the plurality of first nano stacked FET devices and each of the plurality of second stacked FET devices includes an upper stack transistor and a lower stack transistor. A gate cut located between the first row of stacked nano devices and the second row stacked nano devices. An interconnect located within gate cut. The interconnect is connected to a source/drain of one of the lower stacked transistors and the interconnect includes a non-uniform backside surface.

A microelectronic structure includes a first row of stack nano devices that includes a plurality of a first stacked nano FET devices and a second row of stack nano devices that includes a plurality of a second stacked nano FET devices. Each of the plurality of first nano stacked FET devices and each of the plurality of second stacked FET devices includes an upper stack transistor and a lower stack transistor. A gate cut located between the first row of stacked nano devices and the second row stacked nano devices. The gate cut includes a dielectric liner and a dielectric fill layer. An interconnect located within gate cut and the interconnect is connected to a source/drain of one of the lower stacked transistors. The interconnect includes a non-uniform backside surface.

A method includes the steps of forming a first row of stack nano devices that includes a plurality of a first stacked nano FET devices and forming a second row of stack nano devices that includes a plurality of a second stacked nano FET devices. Each of the plurality of first nano stacked FET devices and each of the plurality of second stacked FET devices includes an upper stack transistor and a lower stack transistor. Forming a gate cut located between the first row of stacked nano devices and the second row stacked nano devices. Forming an interconnect located within gate cut. The interconnect is connected to a source/drain of one of the lower stacked transistors and the interconnect includes a non-uniform backside surface.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple stacked nano devices (stacked nanosheet transistors), in accordance with the embodiment of the present invention.

FIG. 2 illustrates a cross section X of the stack of alternating layers of the stacked FET device, in accordance with the embodiment of the present invention.

FIG. 3 illustrates a cross section Y1 of the gate region of the stacked FET device, in accordance with the embodiment of the present invention.

FIG. 4 illustrates a cross section Y2 of the source/drain region of the stacked FET device, in accordance with the embodiment of the present invention.

FIG. 5 illustrates a cross section X of the stack of alternating layers of the stacked FET device after the formation of a bottom dielectric layer and a stack separating layer, the formation of the source/drain region and formation of the inner spacer, in accordance with the embodiment of the present invention.

FIG. 6 illustrates a cross section Y1 of the gate region of the stacked FET device after the formation of a bottom dielectric layer and a stack separating layer, the source/drain region and formation of the inner spacer, in accordance with the embodiment of the present invention.

FIG. 7 illustrates a cross section Y2 of the source/drain region of the stacked FET device after the formation of the source/drain region, in accordance with the embodiment of the present invention.

FIG. 8 illustrates a cross section X of the stack of alternating layers of the stacked FET device after the formation of placeholder trenches, in accordance with the embodiment of the present invention.

FIG. 9 illustrates a cross section Y1 of the gate region of the stacked FET device after the formation of placeholder trenches, in accordance with the embodiment of the present invention.

FIG. 10 illustrates a cross section Y2 of the source/drain region of the stacked FET device after the formation of placeholder trenches, in accordance with the embodiment of the present invention.

FIG. 11 illustrates a cross section Y3 of the source/drain region of the stacked FET device after the formation of placeholder trenches, in accordance with the embodiment of the present invention.

FIG. 12 illustrates a cross section X of the stack of alternating layers of the stacked FET device after the formation of placeholders, formation of the lower and upper source/drains, formation of frontside interlayer dielectric layer, and the formation of the gate, in accordance with the embodiment of the present invention.

FIG. 13 illustrates a cross section Y1 of the gate region of the stacked FET device after the formation of placeholders, formation of the lower and upper source/drains, formation of frontside interlayer dielectric layer, and the formation of the gate, in accordance with the embodiment of the present invention.

FIG. 14 illustrates a cross section Y2 of the source/drain region of the stacked FET device after the formation of placeholders, formation of the lower and upper source/drains, formation of frontside interlayer dielectric layer, and the formation of the gate, in accordance with the embodiment of the present invention.

FIG. 15 illustrates a cross section Y3 of the source/drain region of the stacked FET device after the formation of gate cut trenches, and the formation of the gate, in accordance with the embodiment of the present invention.

FIG. 16 illustrates a cross section X of the stack of alternating layers of the stacked FET device after the formation of gate cut trenches, and the formation of the gate, in accordance with the embodiment of the present invention.

FIG. 17 illustrates a cross section Y1 of the gate region of the stacked FET device after the formation of gate cut trenches, in accordance with the embodiment of the present invention.

FIG. 18 illustrates a cross section Y2 of the source/drain region of the stacked FET device after the formation of gate cut trenches, in accordance with the embodiment of the present invention.

FIG. 19A illustrates a cross section Y3 of the source/drain region of the stacked FET device after the formation of gate cut trenches, in accordance with the embodiment of the present invention.

FIG. 19B illustrates a cross section X2 of the gate cut region of the stacked FET device after formation the gate cut trenches, in accordance with the embodiment of the present invention.

FIG. 20 illustrates a cross section X of the stack of alternating layers of the stacked FET device after formation the gate cut, and the formation of the gate, in accordance with the embodiment of the present invention.

FIG. 21 illustrates a cross section Y1 of the gate region of the stacked FET device after the formation the gate cut, in accordance with the embodiment of the present invention.

FIG. 22 illustrates a cross section Y2 of the source/drain region of the stacked FET device after the formation the gate cut, in accordance with the embodiment of the present invention.

FIG. 23 illustrates a cross section Y3 of the source/drain region of the stacked FET device after the formation the gate cut, in accordance with the embodiment of the present invention.

FIG. 24 illustrates a cross section X of the stack of alternating layers of the stacked FET device after formation of gate trenches, formation of frontside contact trenches and interconnect trench, and the formation of the gate, in accordance with the embodiment of the present invention.

FIG. 25 illustrates a cross section Y1 of the gate region of the stacked FET device after the formation of gate trenches, formation of frontside contact trenches and interconnect trench, in accordance with the embodiment of the present invention.

FIG. 26 illustrates a cross section Y2 of the source/drain region of the stacked FET device after the formation of gate trenches, formation of frontside contact trenches and interconnect trench, in accordance with the embodiment of the present invention.

FIG. 27A illustrates a cross section Y3 of the source/drain region of the stacked FET device after the formation of gate trenches, formation of frontside contact trenches and interconnect trench, in accordance with the embodiment of the present invention.

FIG. 27B illustrates a cross section X2 of the gate cut region of the stacked FET device after the formation of interconnect trench, in accordance with the embodiment of the present invention.

FIG. 28 illustrates a cross section X of the stack of alternating layers of the stacked FET device after formation of the frontside contacts, gate contacts and the interconnect, in accordance with the embodiment of the present invention.

FIG. 29 illustrates a cross section Y1 of the gate region of the stacked FET device after formation the frontside contacts, gate contacts and the interconnect, in accordance with the embodiment of the present invention.

FIG. 30 illustrates a cross section Y2 of the source/drain region of the stacked FET device after formation the frontside contacts, gate contacts and the interconnect, in accordance with the embodiment of the present invention.

FIG. 31A illustrates a cross section Y3 of the source/drain region of the stacked FET device after formation the frontside contacts, gate contacts and the interconnect, in accordance with the embodiment of the present invention.

FIG. 31B illustrates a cross section X2 of the gate cut region of the stacked FET device after the formation of interconnect, in accordance with the embodiment of the present invention.

FIG. 32 illustrates a cross section X of the stack of alternating layers of the stacked FET device after formation of the back-end-of-the-line (BEOL) layer and formation of the carrier wafer, flipping the stacked nano device over for backside processing, and removal of the first substrate, gate contacts and the interconnect, in accordance with the embodiment of the present invention.

FIG. 33 illustrates a cross section Y1 of the gate region of the stacked FET device after formation of the back-end-of-the-line (BEOL) layer and formation of the carrier wafer, flipping the stacked nano device over for backside processing, and removal of the first substrate, in accordance with the embodiment of the present invention.

FIG. 34 illustrates a cross section Y2 of the source/drain region of the stacked FET device after formation of the back-end-of-the-line (BEOL) layer and formation of the carrier wafer, flipping the stacked nano device over for backside processing, and removal of the first substrate, in accordance with the embodiment of the present invention.

FIG. 35 illustrates a cross section Y3 of the source/drain region of the stacked FET device after formation the back-end-of-the-line (BEOL) layer and formation of the carrier wafer, flipping the stacked nano device over for backside processing, and removal of the first substrate, in accordance with the embodiment of the present invention.

FIG. 36 illustrates a cross section X of the stack of alternating layers of the stacked FET device after removal of the etch stop and the second substrate and the formation of the backside interlayer dielectric layer, in accordance with the embodiment of the present invention.

FIG. 37 illustrates a cross section Y1 of the gate region of the stacked FET device after removal of the etch stop and the second substrate and the formation of the backside interlayer dielectric layer, in accordance with the embodiment of the present invention.

FIG. 38 illustrates a cross section Y2 of the source/drain region of the stacked FET device after removal of the etch stop and the second substrate and the formation of the backside interlayer dielectric layer, in accordance with the embodiment of the present invention.

FIG. 39 illustrates a cross section Y3 of the source/drain region of the stacked FET device after removal of the etch stop and the second substrate and the formation of the backside interlayer dielectric layer, in accordance with the embodiment of the present invention.

FIG. 40 illustrates a cross section X of the stack of alternating layers of the stacked FET device after removal of the placeholders and formation of the backside contacts, in accordance with the embodiment of the present invention.

FIG. 41 illustrates a cross section Y1 of the gate region of the stacked FET device after removal of the placeholders and formation of the backside contacts, in accordance with the embodiment of the present invention.

FIG. 42 illustrates a cross section Y2 of the source/drain region of the stacked FET device after removal of the placeholders and formation of the backside contacts, in accordance with the embodiment of the present invention.

FIG. 43 illustrates a cross section Y3 of the source/drain region of the stacked FET device after removal of the placeholders and formation of the backside contacts, in accordance with the embodiment of the present invention.

FIG. 44 illustrates a cross section X of the stack of alternating layers of the stacked FET device after formation of a third lithography layer and etching of the interconnect extension and the center portion of the interconnect, in accordance with the embodiment of the present invention.

FIG. 45 illustrates a cross section Y1 of the gate region of the stacked FET device after formation of the third lithography layer and etching of the interconnect extension and the center portion of the interconnect, in accordance with the embodiment of the present invention.

FIG. 46 illustrates a cross section Y2 of the source/drain region of the stacked FET device after formation of the third lithography layer and etching of the interconnect extension and the center portion of the interconnect, in accordance with the embodiment of the present invention.

FIG. 47A illustrates a cross section Y3 of the source/drain region of the stacked FET device after formation of the third lithography layer and etching of the interconnect extension and the center portion of the interconnect, in accordance with the embodiment of the present invention.

FIG. 47B illustrates a cross section X2 of the gate cut region of the stacked FET device after formation of the third lithography layer and etching of the interconnect extension and the center portion of the interconnect, in accordance with the embodiment of the present invention.

FIG. 48 illustrates a cross section X of the stack of alternating layers of the stacked FET device after formation of additional backside interlayer dielectric layer, formation of metal lines, and the formation of a backside-power-distribution-network, in accordance with the embodiment of the present invention.

FIG. 49 illustrates a cross section Y1 of the gate region of the stacked FET device after formation of additional backside interlayer dielectric layer, formation of metal lines, and the formation of a backside-power-distribution-network, in accordance with the embodiment of the present invention.

FIG. 50 illustrates a cross section Y2 of the source/drain region of the stacked FET device after formation of additional backside interlayer dielectric layer, formation of metal lines, and the formation of a backside-power-distribution-network, in accordance with the embodiment of the present invention.

FIG. 51A illustrates a cross section Y3 of the source/drain region of the stacked FET device after formation of additional backside interlayer dielectric layer, formation of metal lines, and the formation of a backside-power-distribution-network, in accordance with the embodiment of the present invention.

FIG. 51B illustrates a cross section X2 of the gate cut region of the stacked FET device after formation of additional backside interlayer dielectric layer, formation of metal lines, and the formation of a backside-power-distribution-network, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming backside connections in stacked FET devices, specifically forming backside connections to the lower stacked device. Multiple considerations need to be considered prior to formation of backside connections to the lower stacked device. For example, spacing of the frontside and backside connections, how the connections are connected to the BSPDN or the BEOL layers, spacing of the devices, shortages caused by the connections, and other considerations. The backside connections could cause shortages because the connection/metal component extends across multiple metal lines/power rails. The present invention forms a unique structure for the backside connection that extends through the gate cut while avoiding multiple backside/buried power rails as the backside connection connects to the lower stack of the stacked FET.

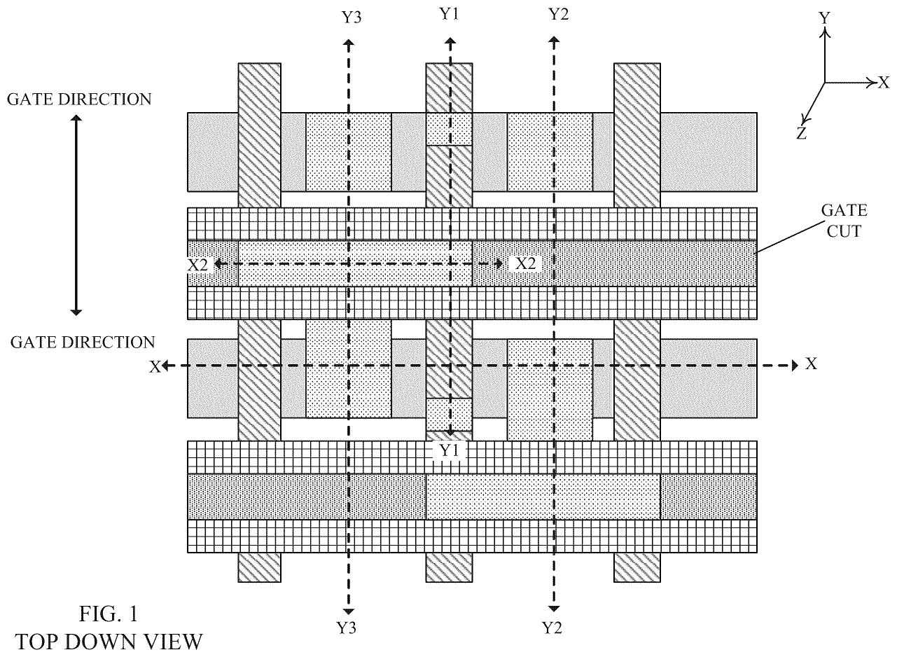

FIG. 1 illustrates a top-down view of multiple stacked nano devices, or stacked nanosheet transistors, which can be comprised of electronic components such as transistors, in accordance with the embodiment of the present invention. The cross-section X extends horizontally through the stack/row of a plurality of nanostack FET devices, where the cross-section is perpendicular to the gate direction. The cross-section X2 extends horizontally through the gate cut region, where the cross-section is perpendicular to the gate direction. Cross section Y1 is perpendicular to cross section X and in parallel with the gate direction, where cross section Y1 is through a gate region that spans across multiple stacked nano stacks. Cross section Y2 is perpendicular to cross section X and in parallel with the gate direction, where cross section Y2 is through a first source region that spans across multiple stacked nano stacks. Cross section Y3 is perpendicular to cross section X and in parallel with the gate direction, where cross section Y3 is through a second source/drain region that spans across multiple stacked nano stacks.

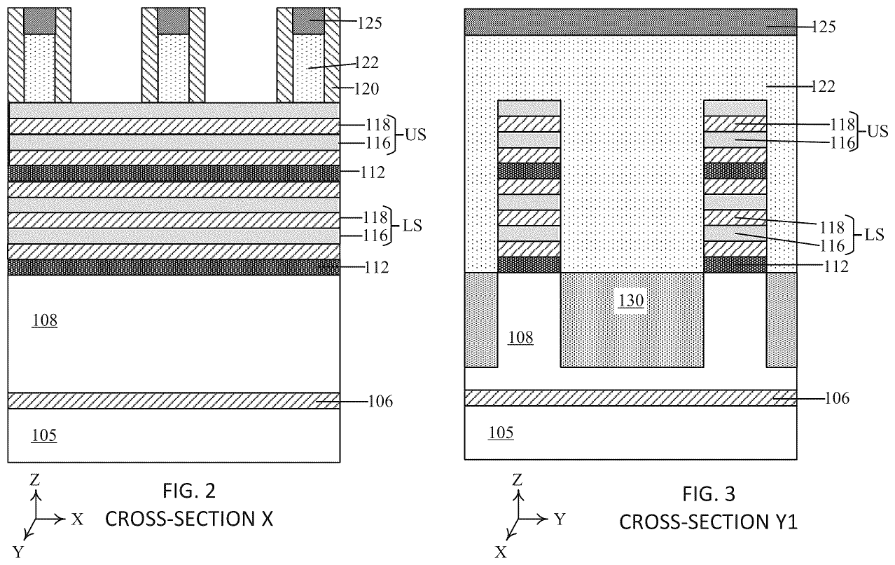

Referring now to FIGS. 2, 3, and 4, a structure is shown during an intermediate step of a method of fabricating stacked nano devices, such as, a stacked nanosheet transistor structure after formation of the dummy gate 122 located on top of the alternating layers that will form the stacked nano device, according to an embodiment of the invention.

FIGS. 2, 3, and 4 illustrate the processing stage of the structure after formation of the dummy gate 122 located on top of the alternating layers. FIG. 2 illustrates a first substrate 105, an etch stop 106, a second substrate 108, a first sacrificial layer 112, a lower stack LS, an upper stack UP, a dummy gate 122, a gate spacer 120, and hardmask 125.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si, SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

The first sacrificial layer 112 can be comprised of, for example, SiGe, where Ge is in the range of about 45% to 70%. The high percentage of Ge in the first sacrificial layer 112 allows for selective targeting of the first sacrificial layer 112 over the plurality of sacrificial layers 118 that are included in the alternating layers of the lower stack LS and the upper stack US. The lower stack LS is comprised of alternating layers of channel layers 116 and sacrificial layers 118. The upper stack US is comprised of alternating layers of channel layers 116 and sacrificial layers 118. The first sacrificial layer 112 separates the lower stack LS and the upper stack US. The sacrificial layers 118 located in the lower stack LS and the upper stack US can be comprised of, for example, SiGe, where Ge is in the range of about 15% to 35%. Channel layers 116 located in the lower stack LS and the upper stack US are nanosheets comprised of, for example, Si.

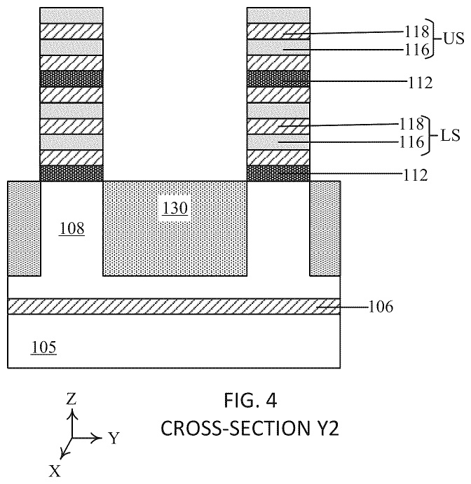

FIG. 3 illustrates multiple stacked nano stack enclosed by the dummy gate 122. A trench (not shown) was formed in the second substrate 108 when the alternating layers and the first sacrificial layer 112 were separated into multiple columns. The trenches were filled in with a shallow trench isolation layer 130. FIGS. 3 and 4 illustrate that the upper stack US and the lower stack LS have the same width, but this is not necessary. The lower stack LS can have a first width (measured in the Y-axis) and the upper stack US has a second width (measured in the Y-axis), where the first width is larger than the second width. The differences in width between the upper stack US and the lower stack LS will allow for the formation of source/drains having different widths (not shown but will be described in further detail below). FIG. 4 illustrates how the source/drain region is not enclosed by dummy gate 122.

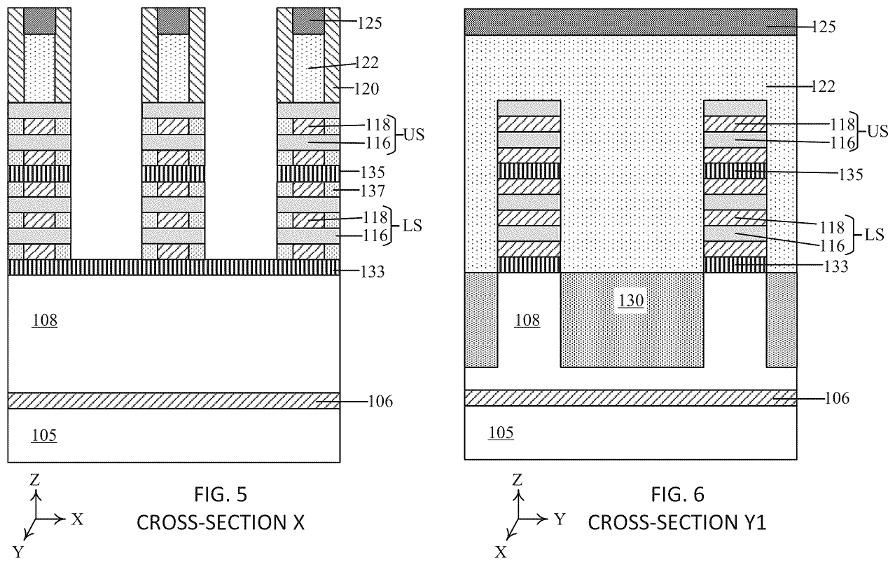

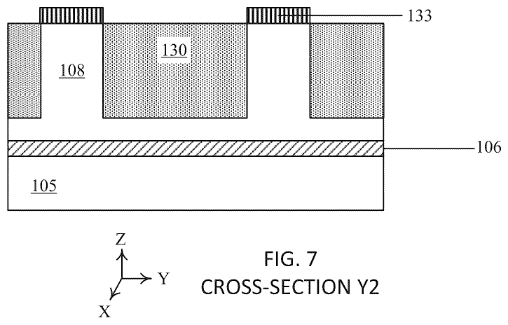

FIGS. 5, 6, and 7 illustrate the processing stage of the structure after the formation of a bottom dielectric layer 133 and a stack separating layer 135, the source/drain region and formation of the inner spacer 137. The first sacrificial layer 112 is selectively targeted and removed and replaced with a bottom dielectric layer 133 and a stack separating layer 135. The first sacrificial layer 112 was selectively targeted and removed because of the higher Ge percentage. The nano stack columns are separated into multiple sections to form a source/drain region between each of the sections. The sacrificial layer 118 of the lower stack LS and the upper stack US is recessed to form a void/space. An inner spacer 137 is formed in the void/spaces in the lower stack LS and the upper stack US.

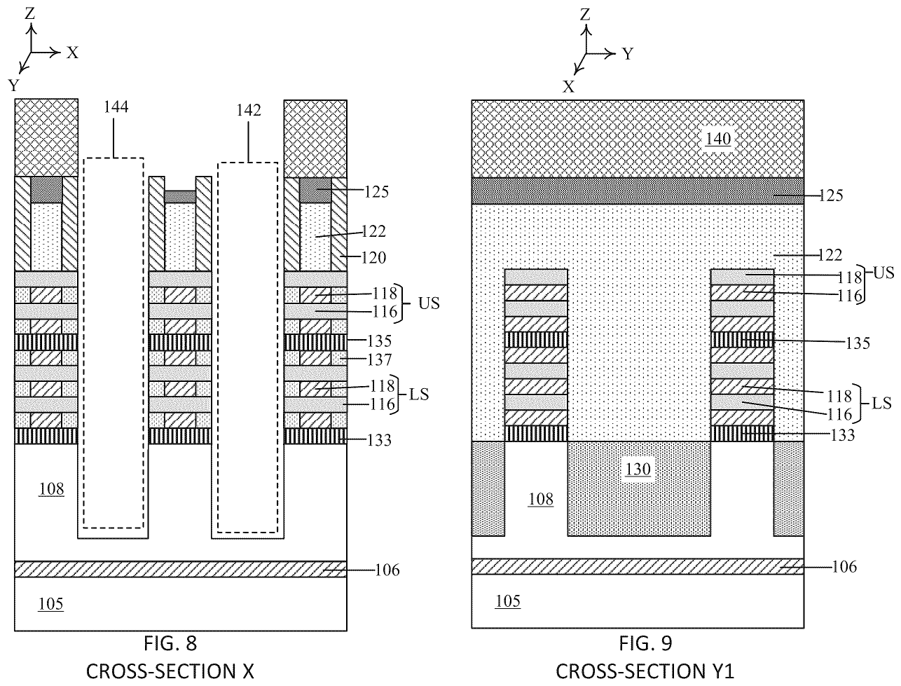

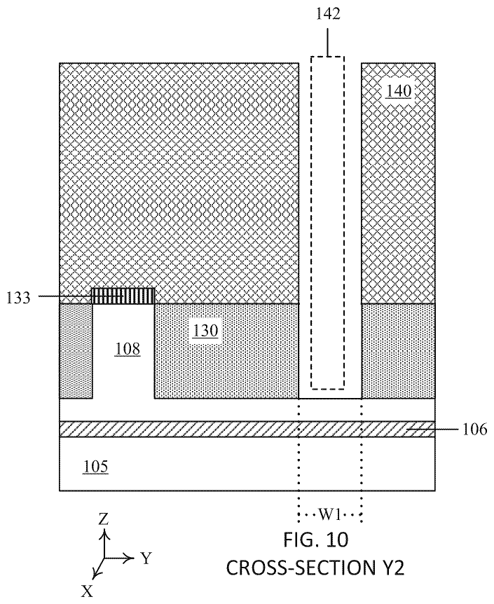

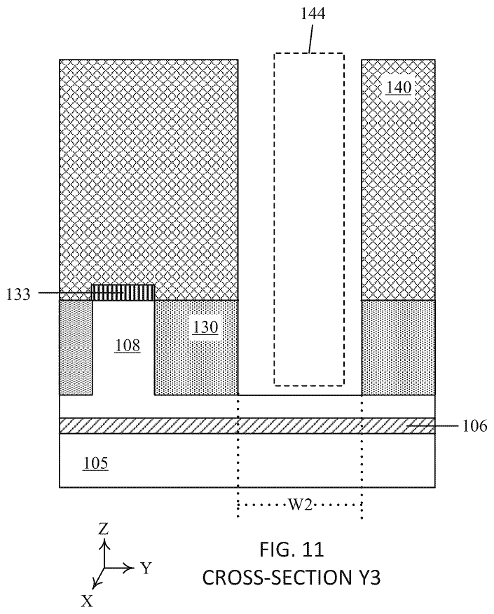

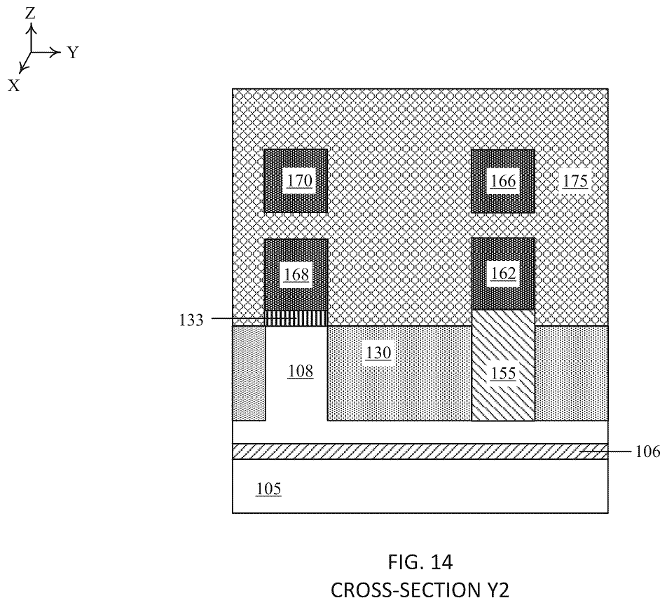

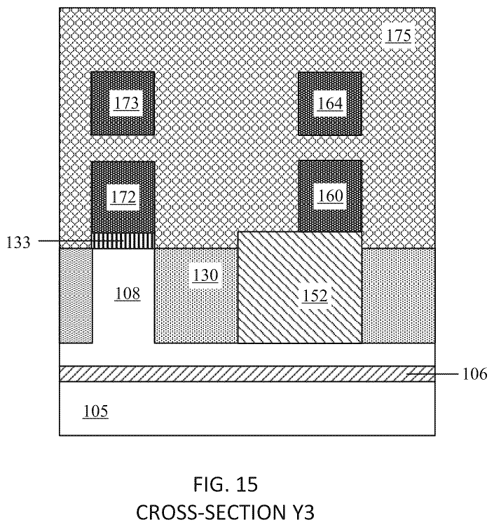

FIGS. 8, 9, 10 and 11 illustrate the processing stage of the structure after the formation of placeholder trenches 142, 144. A lithography layer 140 is formed on the exposed surface and patterned to expose areas where the placeholder trenches 142, 144 will be formed. The underlying layers are etched to form a plurality of placeholder trenches 142, 144. The placeholder trenches 142, 144 are located in the source/drain regions so that the placeholder 152, 155 will be located beneath the source/drains 160, 162, of the lower stack LS. A placeholder trench 142, 144 does not need to be placed beneath each of the source/drains of the lower stack LS (see, for example, FIGS. 14 and 15). The placeholders trenches 142, 144 will be utilized to form backside contacts that will connect to the backside surface of the source/drains 160, 162. The dimensions of the placeholder trenches 142 and 144 can be the same or different. FIGS. 10 and 11 illustrate how the dimensions of the placeholder trenches 142, 144 differ in the Y-axis direction (or gate direction). The first placeholder trench 142 has a width W1 in the Y-axis direction (or gate direction) and the second placeholder trench 144 has a width W2 in the Y-axis direction (or gate direction). The width W2 of the second placeholder trench 144 is larger than the width W1 of the first placeholder trench 142. The larger width W2 of the second placeholder trench 144 ensures that the second placeholder 152 will extend into the location where the gate cut 200 will be located. This allows for interconnect 226 to be formed within the gate cut 200 and connected to the second placeholder 152.

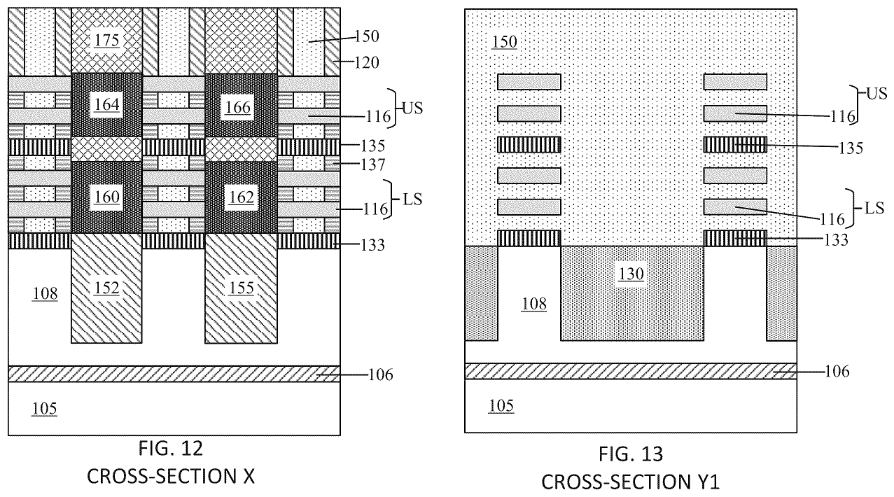

FIGS. 12, 13, 14 and 15 illustrate the processing stage of the structure after the formation of placeholders 152, 155, formation of the lower and upper source/drains 160, 162, 164, 166, 168, 170, 172, 173, formation of frontside interlayer dielectric layer 175, and the formation of the gate 150. The first placeholder 155 is formed in the bottom of the first placeholder trench 142 and the second placeholder 152 is formed in the bottom of the second placeholder trench 144. The lower source/drains 160, 162, 168, and 172 and the upper source/drains 164, 166, 170, and 173 are formed. FIG. 14 illustrates that the lower source/drains 162 and 168 have a width that is substantially the same as the width of the upper source/drains 166, and 170. The widths of the lower source/drains can be larger than the width of the upper source drains (not shown).

The lower source/drains 160, 162, 168, and 172 and the upper source/drains 164, 166, 170, and 173 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

A frontside interlayer dielectric layer 175 is formed around the lower source/drains 160, 162, 168, and 172 and the upper source/drains 164, 166, 170, and 173. The dummy gate 122, the hardmask 125 and the sacrificial layers 118 of the lower stack LS and the upper stack US are removed. Gate 150 is formed in the space created by the removal of these layers. Gate 150 can be comprised of, for example, a gate dielectric liner, such as high-k dielectric like HfO₂, ZrO₂, HfLₐOₓ, etc., and work function layers, such as TIN, TiAIC, TiC, etc., and conductive metal fills, like W.

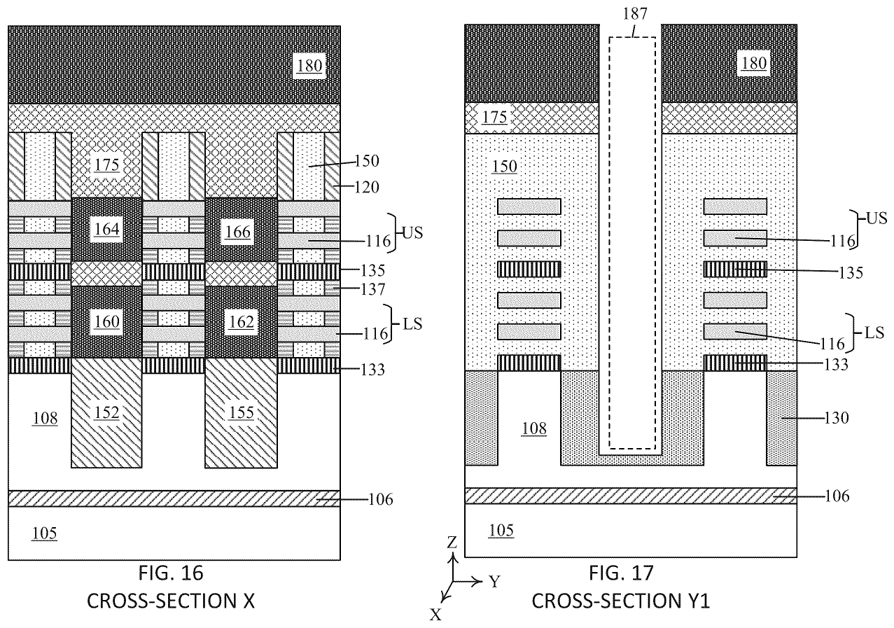

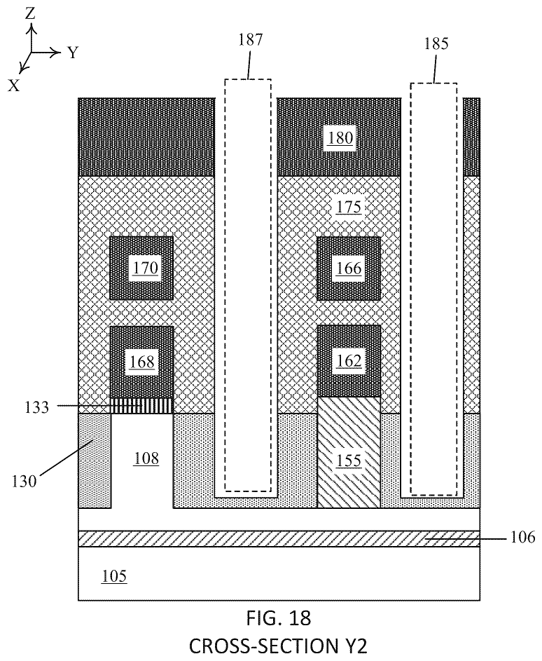

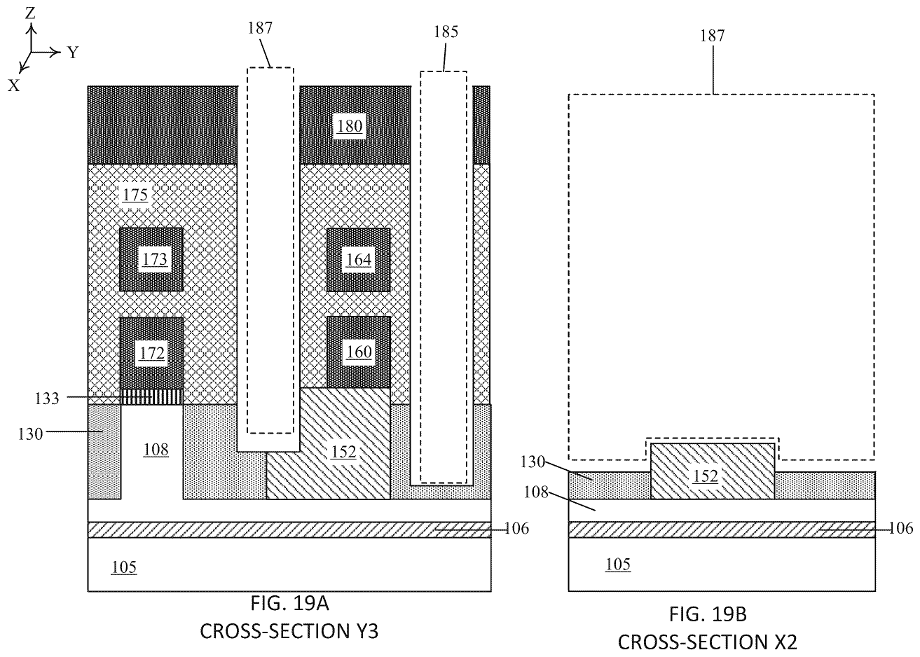

FIGS. 16, 17, 18, 19A and 19B illustrate the processing stage of the structure after the formation of gate cut trenches 182, 185. The frontside interlayer dielectric layer 175 height is extended by adding additional dielectric material, so that the frontside interlayer dielectric layer 172 extends over the gate 150. A second lithography layer 180 is formed on top of the exposed surface and patterned. A plurality of gate cut trenches 182, 185 are formed between nano stacked devices columns to separate the gates 150 of the devices. The first gate trench 182 extends downwards to a uniform distance into the shallow trench isolation layer 130 but that does not happen within the second gate trench 187. The extended second placeholder 152 affects how the second gate cut trench 187 is formed. The material of the second placeholder 152 affects the etch rate during the formation of the second gate cut trench 187, thus creating a step formation within the second gate cut trench 187. A portion of the second gate cut trench 187 located above the second placeholder 152 does not extend downwards to a same depth as the rest of the second gate cut trench 187, as illustrated in FIGS. 19A and 19B. FIG. 19A illustrates a depth difference between the first gate cut trench 182 and the second gate cut trench 187, and FIG. 19B illustrates the step within the second gate cut trench 187.

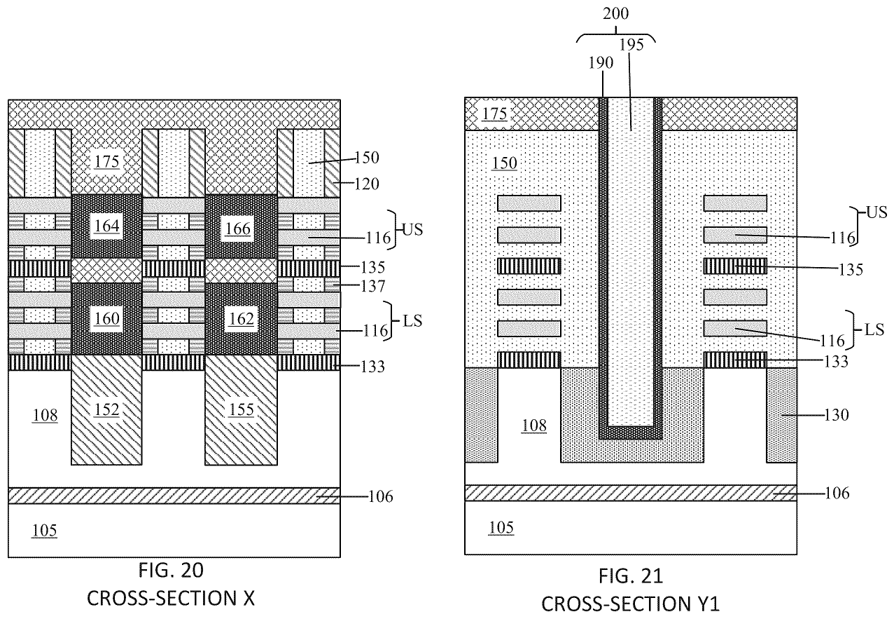

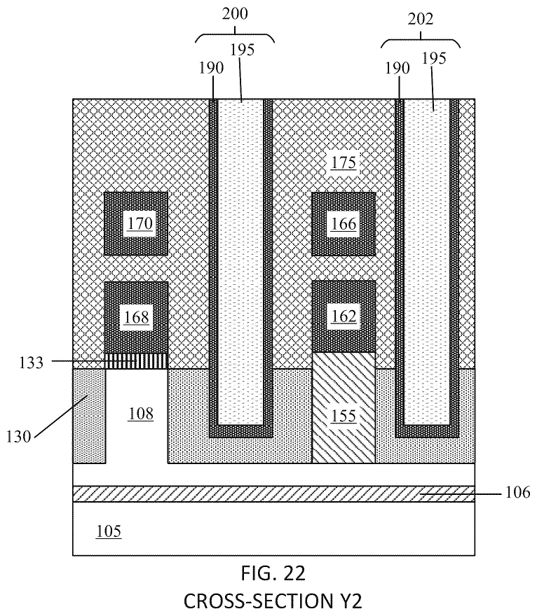

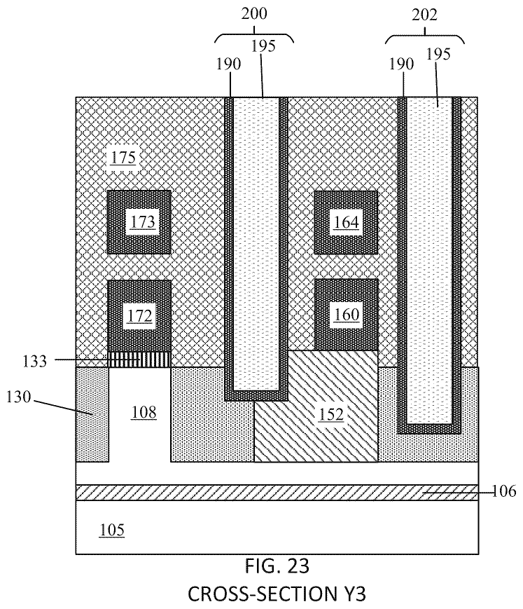

FIGS. 20, 21, 22 and 23 illustrate the processing stage of the structure after the formation of gate cut 200, 202. The first gate cut 200 is formed in the second gate cut trench 187 and the second gate cut 202 is formed in the first gate cut trench 185. The first gate cut 200 and the second gate cut 202 each include a dielectric liner 190 and a dielectric fill layer 195. A portion of the first gate cut 200 is formed directly on top of the second placeholder 152, as illustrated in FIG. 23, and portions of the first gate cut 200 are formed directly on top of the shallow trench isolation layer 130, as illustrated in FIGS. 21 and 22.

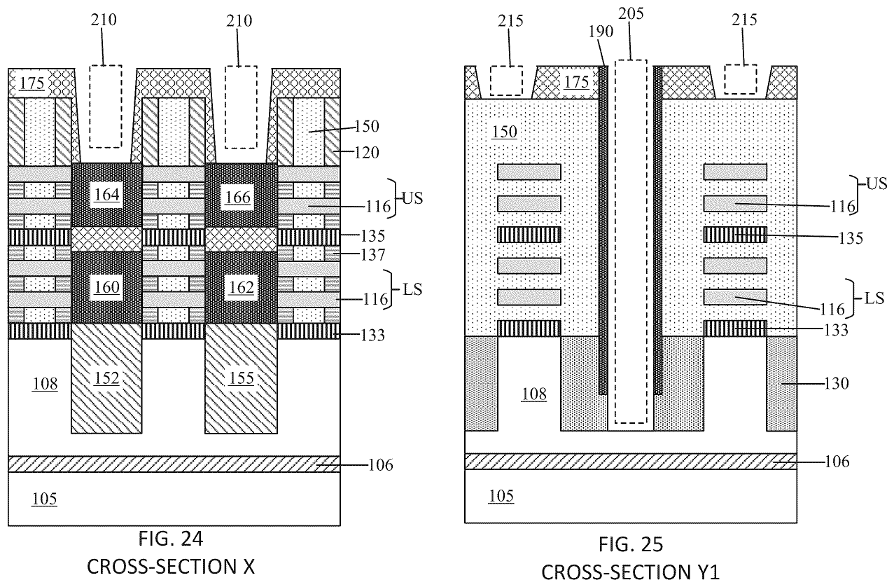

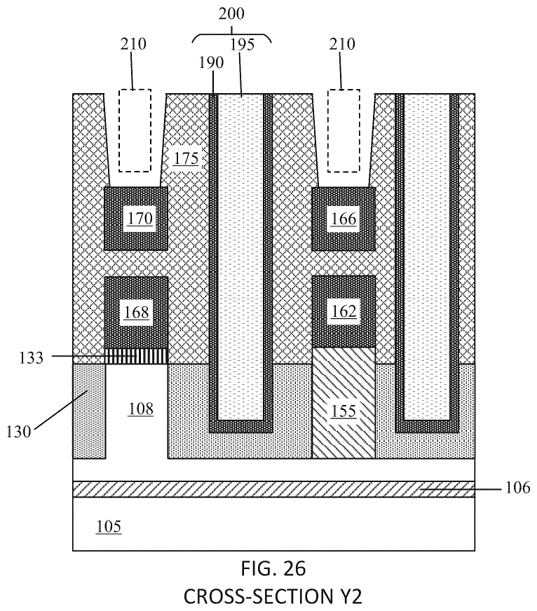

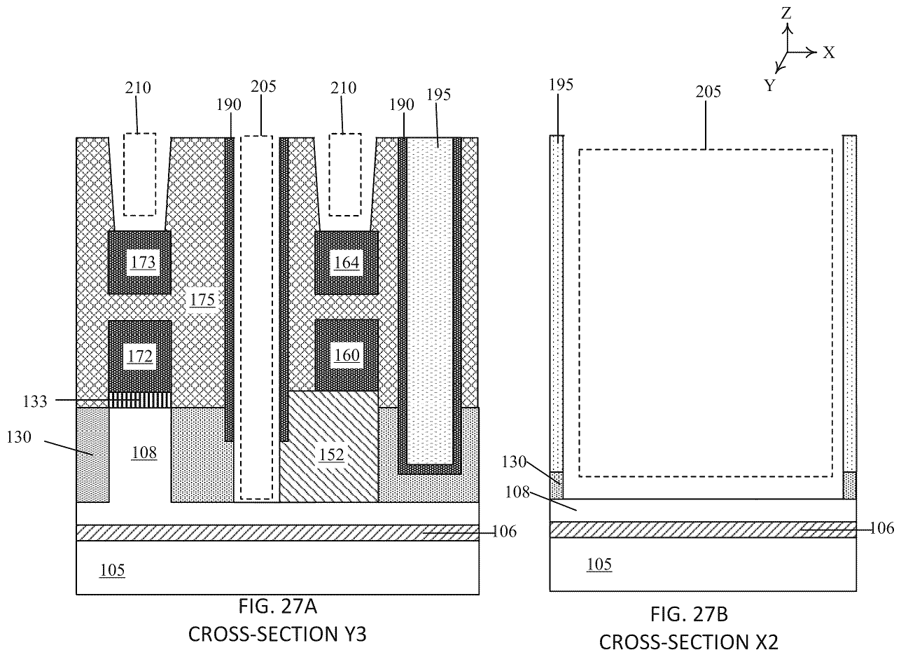

FIGS. 24, 25, 26, 27A and 27B illustrate the processing stage of the structure after the formation of gate trenches 215, formation of frontside contact trenches 210 and interconnect trench 205. A plurality of frontside contact trenches 210 are formed in the frontside interlayer dielectric layer 175 to expose a tops surface of some of the upper source/drains 164, 166, 170 and 173 of the upper stack US. A gate trench 215 is formed in the frontside interlayer dielectric layer 175 to expose a top surface of the gate 150, as illustrated in FIG. 25. FIGS. 25, 27A, and 27 illustrate the formation of the interconnect trench 205 located within the first gate cut 200. FIGS. 26 and 27 illustrate that interconnect trench 205 does not extend completely across (i.e., in the X-axis direction) the first gate cut 200. Interconnect trench 205 extends downwards between sections of the dielectric liner (see, for example, FIG. 27A) and extends downwards through portions of the shallow trench isolation layer 130 and portions of the second placeholder 152. As illustrated in FIG. 27A, an upper portion of the second placeholder 152 is in direct contact with a portion of the dielectric liner 190 and a lower portion of the second placeholder 152 is exposed by the interconnect trench 205.

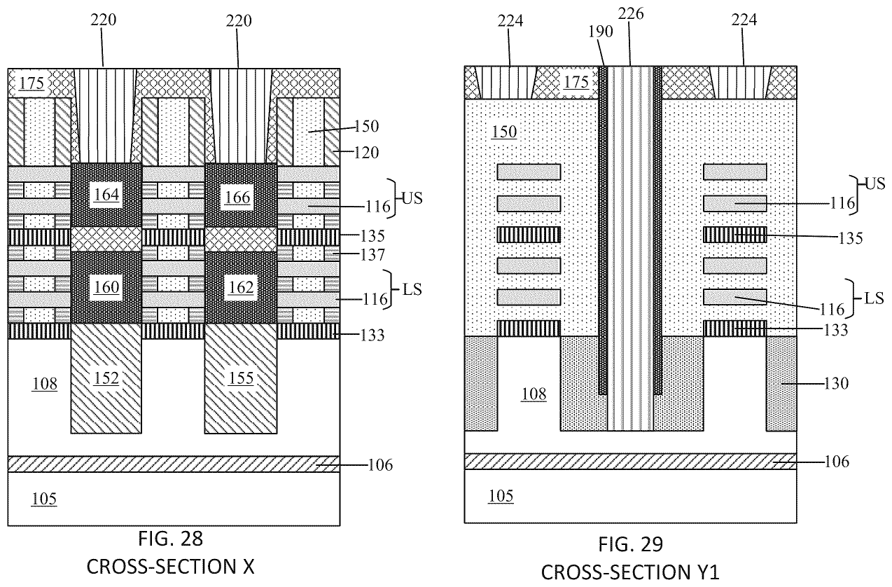

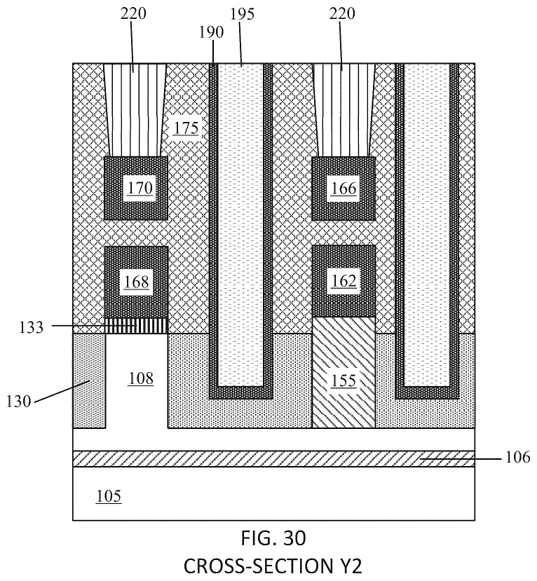

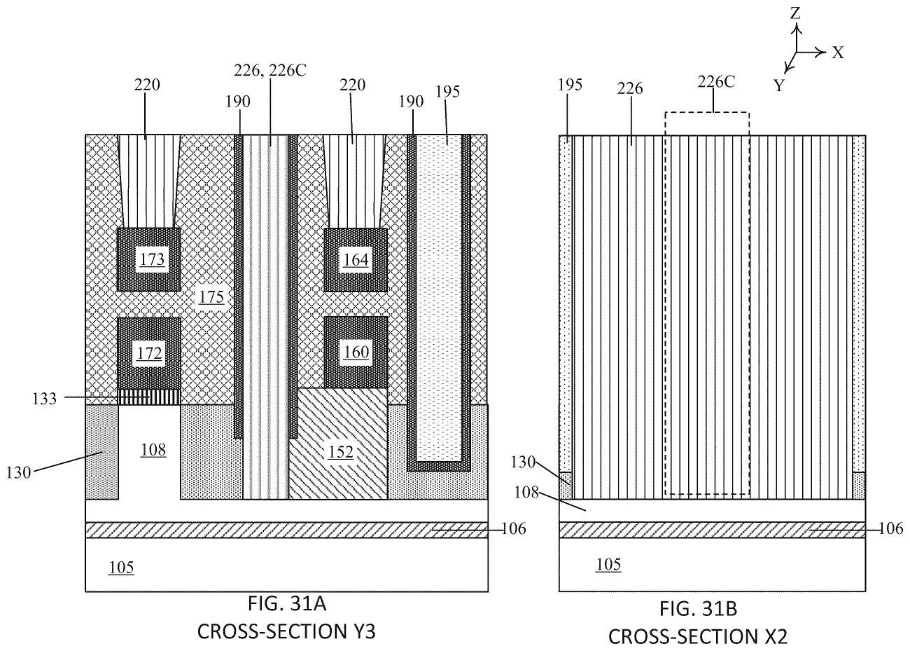

FIGS. 28, 29, 30, 31A and 31B illustrate the processing stage of the structure after formation of the frontside contacts 220, gate contacts224, and the interconnect 226. A metallization process fills the gate trenches 215, formation of frontside contact trenches 210 and interconnect trench 205. FIGS. 28, 30, and 31A illustrate the frontside contacts 220 being located on top of the upper source/drains 164, 166, 170 and 173, respectively. FIG. 29 illustrates that each of the gate contacts 224 is located on top of and in contact with gate 150. FIGS. 29, 31A, and 31B illustrate where a center portion 226C of the interconnect has a lower sidewall that is in direct contact with both the dielectric liner 190 and the second placeholder 152. The center portion 226C does not necessarily need to be located in the center of interconnect 226 but refers to the section of the interconnect 226 that is located directly against the second placeholder 152. The center portion 226C can refer to the center, left, right, or any portion of the interconnect 226 as long as that portion is directly adjacent to and in direct contact with the second placeholder 152.

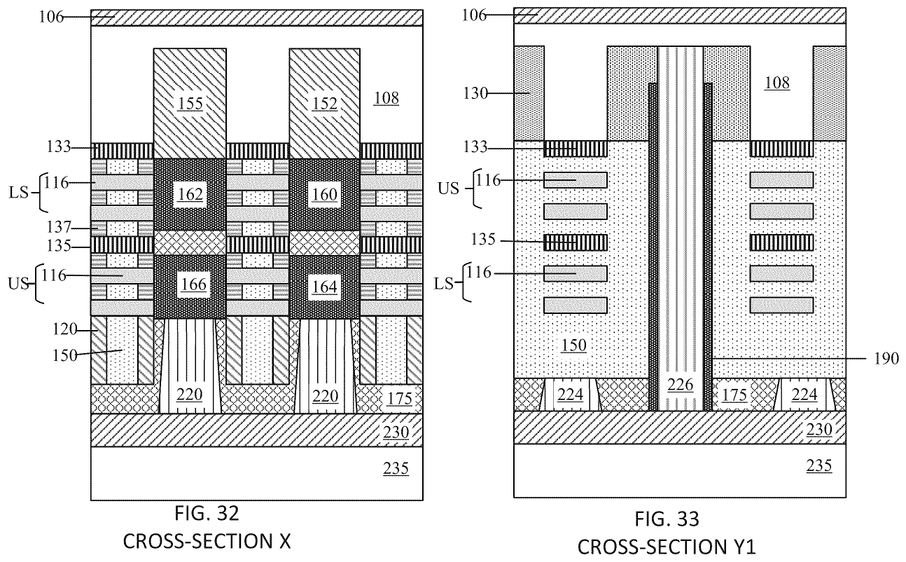

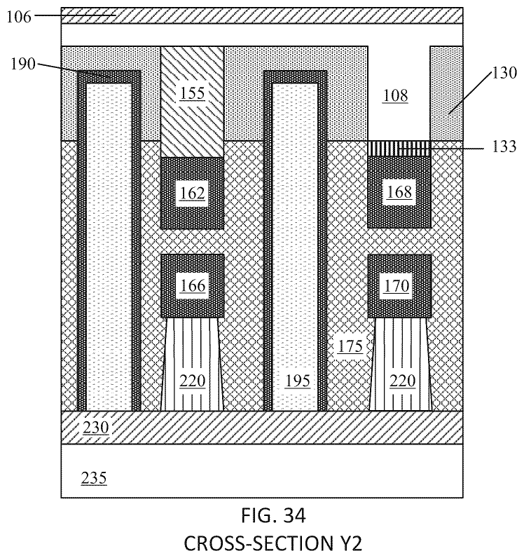

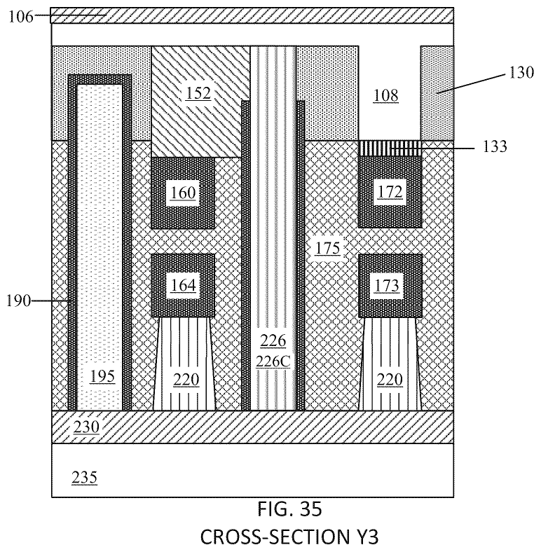

FIGS. 32, 33, 34 and 35 illustrate the processing stage of the structure after formation of the back-end-of-the-line (BEOL) layer 230 and formation of the carrier wafer 235, flipping the stacked nano device over for backside processing, and removal of the first substrate 105. A back-end-of-the-line (BEOL) layer 230 is formed on top of the frontside interlayer dielectric layer 175, the frontside contacts 220, the gate contacts 224, the gate cuts 202, 200, and on top of the interconnect 226. A carrier wafer 235 is attached/formed on top of the BEOL layer 230. The carrier wafer 235 allows for the flipping of the stacked nano FET devices over (or flipping the wafer over) for backside processing. The first substrate 105 is removed to expose the etch stop 106.

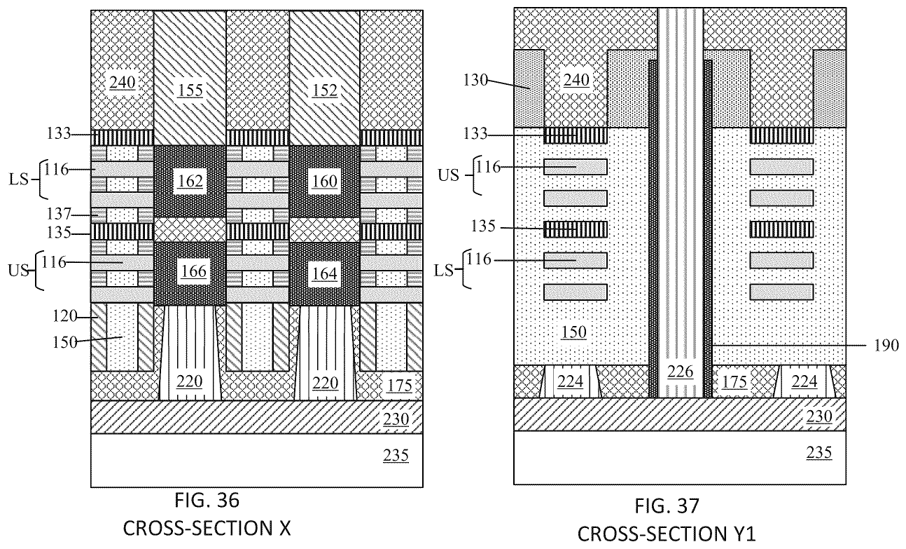

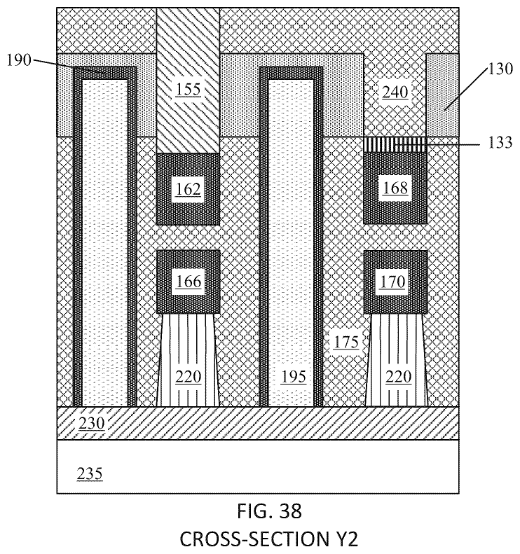

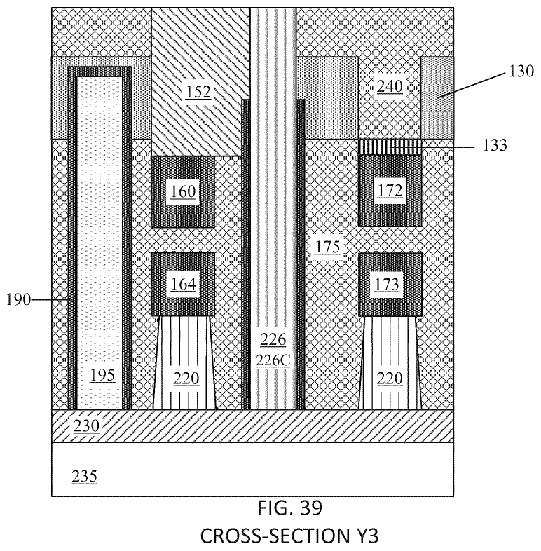

FIGS. 36, 37, 38 and 39 illustrate the processing stage of the structure after removal of the etch stop 106 and the second substrate 108 and the formation of the backside interlayer dielectric layer 240. The etch stop 106 and the second substrate 108 are removed to expose the area around the placeholders 152, 155, the backside surface of the bottom dielectric layer 133 and portions of the interconnect 226. A backside interlayer dielectric layer 240 is formed to fill the space created by the removal of the etch stop 106 and the second substrate 108.

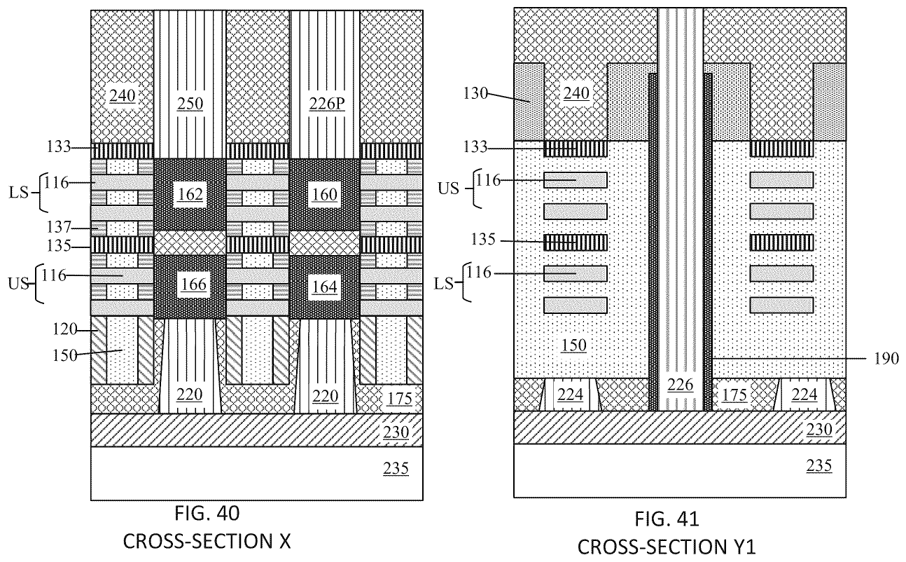

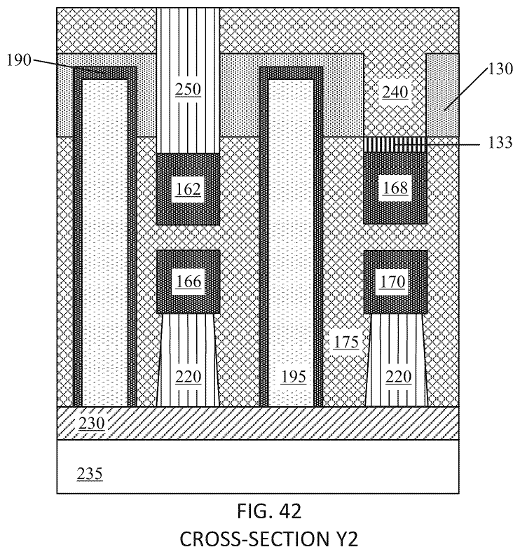

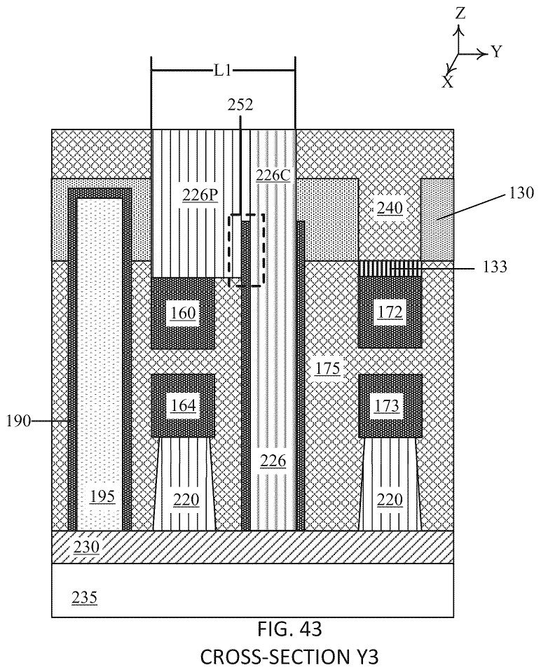

FIGS. 40, 41, 42 and 43 illustrate the processing stage of the structure after removal of the placeholders 152, 155 and formation of the backside contacts. The first placeholder 155 and the second placeholder 152 are removed to expose a backside surface of the lower source/drains 160, 162 respectively. A metallization process forms the first backside contact 250 and interconnect extension 226P, where the backside contact 250 is located on the backside surface of lower source/drain 162 and the interconnect extension 226P is located on the backside surface of lower source/drain 160. The interconnect extension 226P extends off center portion 226C of interconnect 226. A sidewall of the interconnect extension 226P is in direct contact with a portion of the dielectric liner 190 as emphasized by dashed box 252. This portion of the dielectric liner 190 is in direct contact with the interconnect extension 226P and the center portion 226C of the interconnect 226. The portion of the dielectric liner 190 emphasized by dashed box 252 is enclosed by an inverted U-shape profile of interconnect extension 226P and the center portion 226C of the interconnect 226. The interconnect extension 226P is in contact with a first sidewall of the dielectric liner 190, and the center portion 226C of the interconnect 226 is in direct contact with a second sidewall of the dielectric liner 190, such that first sidewall is opposite the second sidewall. Since the interconnect extension 226P and the center portion 226C of have a combined length L1 in across the Y-axis (or in the gate direction). The combined length L1 is long enough to form connections with multiple buried power rails/metal lines thus creating a short between these buried power rails/metal lines. This issue is addressed by changing the height/depth of the interconnect extension 226P and the center portion 226C which is described in detail below.

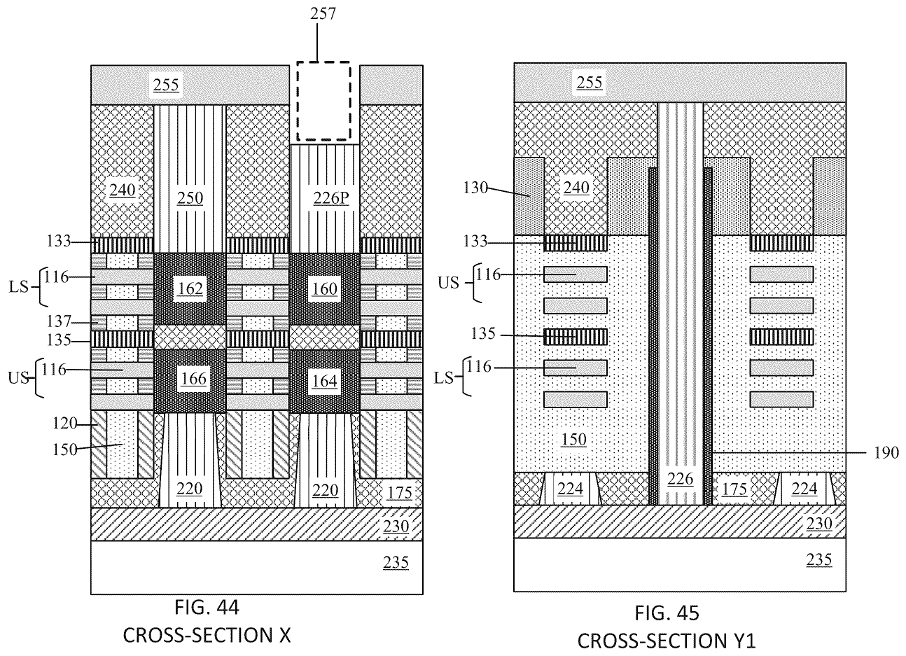

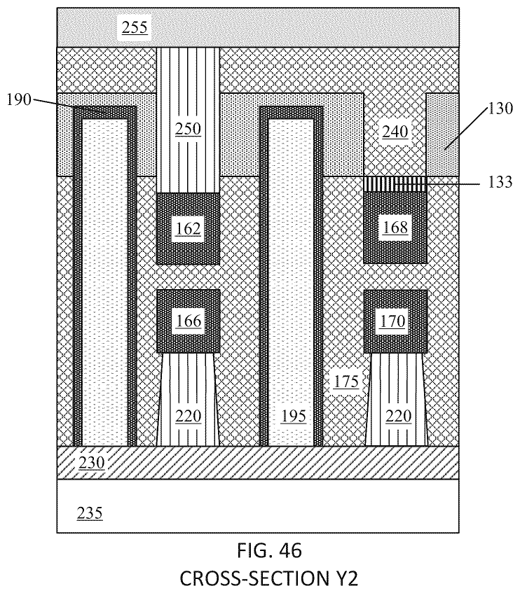

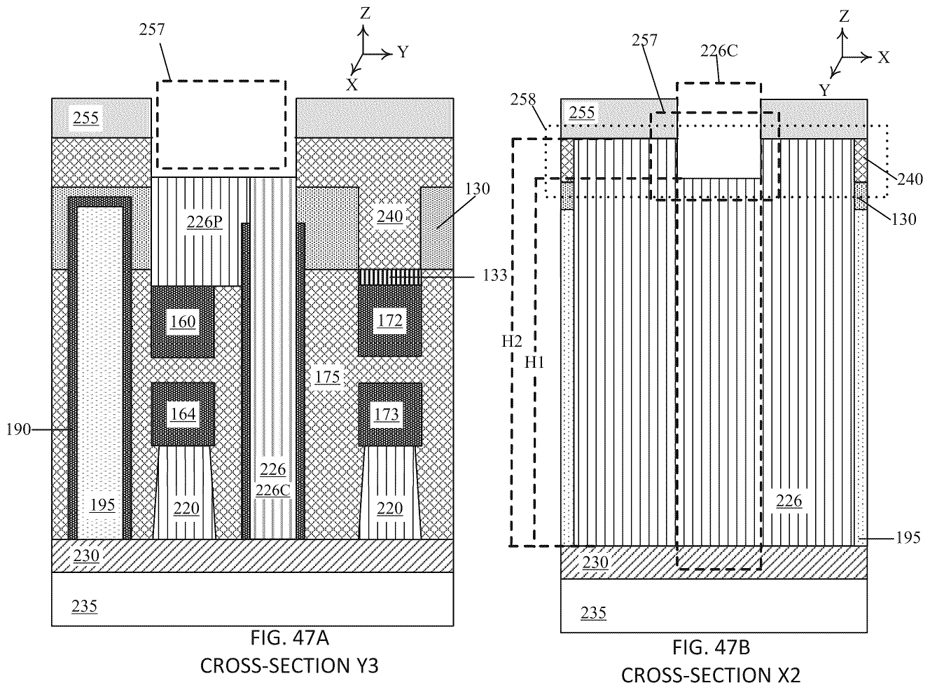

FIGS. 44, 45, 46, 47A and 47B illustrate the processing stage of the structure after formation third lithography layer 255 and etching of the interconnect extension 226P and the center portion 226C of the interconnect 226. A third lithography layer 255 is formed on the backside interlayer dielectric layer 240, on the interconnect extension 226P, and on the interconnect 226. The third lithography layer 225 is patterned to expose the interconnect extension 226P and the center portion 226C of the interconnect 226. The interconnect extension 226P and the center portion 226C of the interconnect 226 are etched to lower height/depth of these sections, as emphasized by dashed box 257 and illustrated in FIGS. 47A and 47B. As illustrated in FIG. 47B the backside portion of the interconnect 226 forms a U-Shape profile (along the X-axis) around the lower section of the center portion 226C as emphasized by dashed box 258. Therefore, the backside surface of the interconnect 226 is located at two different heights/depths, where the backside surface of the central portion 226C has a height H1 (when measured from a frontside surface to a backside surface) that is lower/less than the height H2 (when measured from a frontside surface to a backside surface) of the adjacent sections of the interconnect 226, thus forming the U-shape profile.

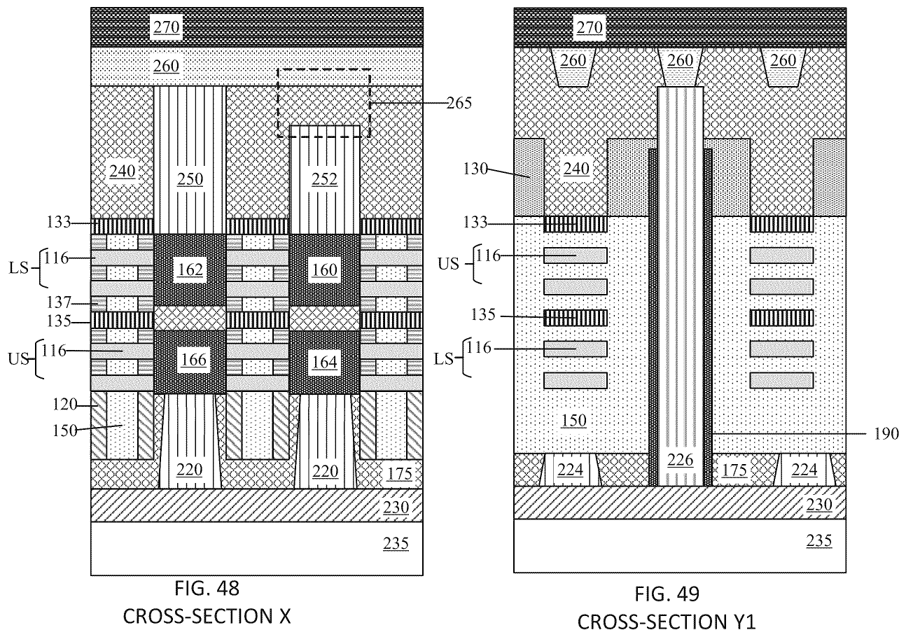

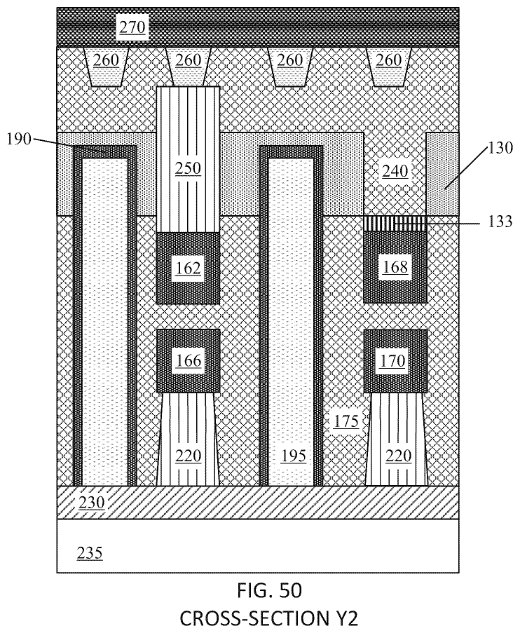

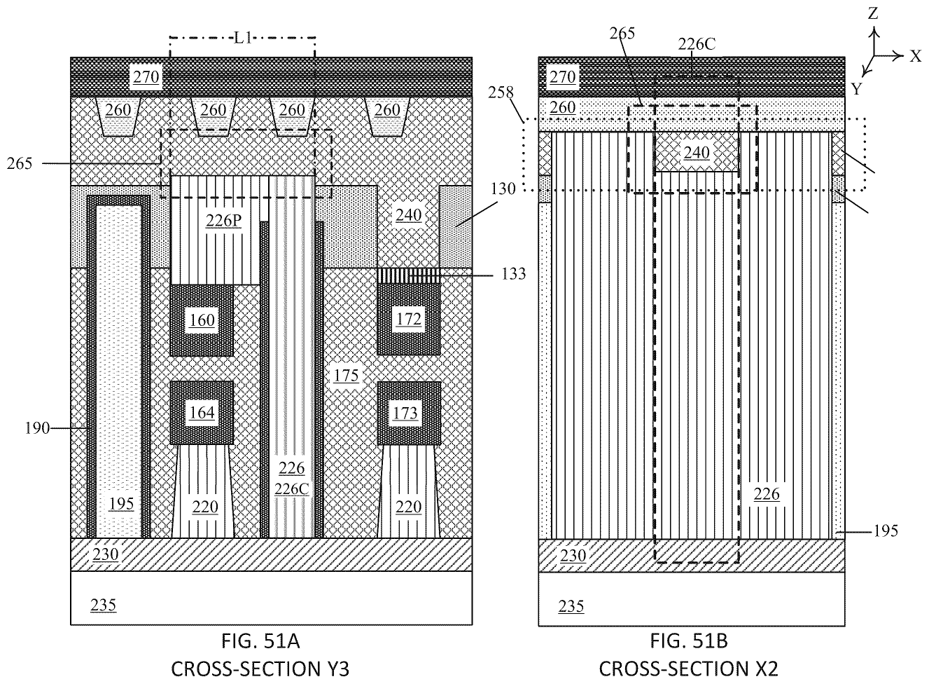

FIGS. 48, 49, 50, 51A and 51B illustrate the processing stage of the structure after formation of additional backside interlayer dielectric layer 240, formation of metal lines 260, and the formation of a backside-power-distribution-network 270. Additional dielectric material is added to the backside interlayer dielectric layer 240. As illustrated in FIGS. 48, 51A, and 51B the backside interlayer dielectric layer is located on the backside surface of the interconnect extension 226P and the backside surface of the center portion 226C of the interconnect 226, as emphasized in dashed box 265. As seen in FIG. 51B, the backside interlayer dielectric layer 240 is located within the recess of center portion 226C of interconnect 226, as emphasized in dashed box 265. A plurality of metal lines 260 are formed in the backside interlayer dielectric layer 240. The metal lines 260 can be, for example, backside power rails (VSS and/or VDD), single lines, or a wire, or any combination thereof. As illustrated in FIG. 51A, the length L1 of the interconnect extension 226P and the center portion 226C of the interconnect 226 is long enough to extend across multiple metal lines 260, as emphasized in dashed box 265. Thus, the lowering/etching of the interconnect extension 226P and the center portion 226C of the interconnect 226 prevents shorting from occurring from the interconnect extension 226P and the center portion 226C of the interconnect 226 touching multiple metal lines 260. As illustrated in FIG. 51B, interconnect 226 is connected to a metal line 260 by the vertical elements (or two segments) of the U-shaped profile (along the X-axis), as emphasized by dashed box 258, while center portion 226C is prevent from contacting the metal line 260, as emphasized by dashed box 265. The backside interlayer dielectric layer 240 is in contact with the backside surface of the interconnect extension 226P and at least one side surface of the interconnect 226. This illustrates that the interconnect does not have a uniform (or has a non-uniform) backside surface because of the step down for the center portion 226C of the interconnect 226. A backside-power-distribution-network 470 is formed on top of the metal lines 260 and the backside interlayer dielectric layer 240. The present disclosure illustrates interconnect 226 being located within the gate cut 200. However, this is not meant to be seen as limiting. Interconnect 226 can be formed in different locations, for example, within the frontside interlayer dielectric layer 175, or a different suitable layer. Interconnect 226 have a non-uniform backside surface, while having a interconnect extension 226P, allows for the connections to be made to components while avoiding the formation of shorts with other backside components (for example, backside power rails, wires, etc.).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first row of stack nano devices that includes a plurality of a first stacked nano FET devices and a second row of stack nano devices that includes a plurality of a second stacked nano FET devices, wherein each of the plurality of first nano stacked FET devices and each of the plurality of second stacked FET devices includes an upper stack transistor and a lower stack transistor;
a gate cut located between the first row of stacked nano devices and the second row stacked nano devices; and
an interconnect located within gate cut, wherein the interconnect is connected to a source/drain of one of the lower stacked transistors, wherein the interconnect includes a non-uniform backside surface.

2. The microelectronic structure of claim 1, wherein the interconnect includes an extension that extends under the source/drain of the lower stack transistor.

3. The microelectronic structure of claim 2, wherein the extension of the interconnect has a first height, when measured from a frontside surface to a backside surface, wherein interconnect has a section that is located adjacent to the extension of the interconnect, wherein the adjacent section of the interconnect has second height, when measured from a frontside surface to a backside surface.

4. The microelectronic structure of claim 3, wherein the second height is larger than the first height, wherein the difference in the first height and the second height causes the non-uniform backside surface of the interconnect.

5. The microelectronic structure of claim 2, further comprising a plurality of metal lines located on a backside of the first row of stacked nano devices and the second row stacked nano devices.

6. The microelectronic structure of claim 5, the extension of the interconnect extends across multiple metal lines of the plurality of metal lines.

7. The microelectronic structure of claim 6, further comprising:
a backside interlayer dielectric layer located between the extension of the interconnect and the plurality of metal lines.

8. The microelectronic structure of claim 7, wherein the interconnect is connected to one of the metal lines of the plurality of metal lines.

9. The microelectronic structure of claim 8, wherein the backside interlayer dielectric layer is in contact with a backside surface of the extension of the interconnect and a side surface of the interconnect.

10. A microelectronic structure comprising:
a first row of stack nano devices that includes a plurality of a first stacked nano FET devices and a second row of stack nano devices that includes a plurality of a second stacked nano FET devices, wherein each of the plurality of first nano stacked FET devices and each of the plurality of second stacked FET devices includes an upper stack transistor and a lower stack transistor;
a gate cut located between the first row of stacked nano devices and the second row stacked nano devices, wherein the gate cut includes a dielectric liner and a dielectric fill layer; and
an interconnect located within gate cut, wherein the interconnect is connected to a source/drain of one of the lower stacked transistors, wherein the interconnect includes a non-uniform backside surface.

11. The microelectronic structure of claim 10, wherein the interconnect includes an extension that extends under the source/drain of the lower stack transistor.

12. The microelectronic structure of claim 11, further comprising a plurality of metal lines located on a backside the first row of stacked nano devices and the second row stacked nano devices.

13. The microelectronic structure of claim 12, the extension of the interconnect extends across multiple metal lines of the plurality of metal lines.

14. The microelectronic structure of claim 13, further comprising:
a backside interlayer dielectric layer located between the extension of the interconnect and the plurality of metal lines.

15. The microelectronic structure of claim 14, wherein the interconnect is connected to one of the metal lines of the plurality of metal lines.

16. The microelectronic structure of claim 15, wherein the backside interlayer dielectric layer is in contact with a backside surface of the extension of the interconnect and a side surface of the interconnect.

17. The microelectronic structure of claim 11, wherein the extension of the interconnect is in direct contact with a backside surface of the source/drain of the lower stack and the extension of the interconnect is in direct contact with a first sidewall of the dielectric liner.

18. The microelectronic structure of claim 17, wherein the interconnect is direct contact with a second sidewall of the dielectric liner, wherein the first sidewall of the dielectric liner is the opposite the second sidewall of the dielectric liner.

19. A method comprising:
forming a first row of stack nano devices that includes a plurality of a first stacked nano FET devices and forming a second row of stack nano devices that includes a plurality of a second stacked nano FET devices, wherein each of the plurality of first nano stacked FET devices and each of the plurality of second stacked FET devices includes an upper stack transistor and a lower stack transistor;
forming a gate cut located between the first row of stacked nano devices and the second row stacked nano devices; and
forming an interconnect located within gate cut, wherein the interconnect is connected to a source/drain of one of the lower stacked transistors, wherein the interconnect includes a non-uniform backside surface.

20. The method of claim 19, wherein the gate cut includes a dielectric liner and a dielectric fill layer, wherein the extension of the interconnect is in direct contact with a backside surface of the source/drain of the lower stack and the extension of the interconnect is in direct contact with a first sidewall of the dielectric liner, wherein the interconnect is direct contact with a second sidewall of the dielectric liner, and wherein the first sidewall of the dielectric liner is the opposite the second sidewall of the dielectric liner.
